(19) United States
(12) Patent Application Publication
(10) Pub. No.: US 2006/0056503 A1
(43) Pub. Date: Mar. 16, 2006

(54) Pipelined parallel decision feedback decoders for high-speed communication systems

(75) Inventors: Parhi K. Keshab, Maple Grove, MN (US); Yongru Gu, Sacramento, CA (US)

Correspondence Address: SHUMAKER & SIEFFERT, P. A., 8425 SEASONS PARKWAY, SUITE 105, ST. PAUL, MN, 55125, US

(73) Assignee: Regents of the University of Minnesota, Minneapolis, MN (US)

(21) Appl. No.: 11/225,825

(22) Filed: Sep. 13, 2005

Related U.S. Application Data
(60) Provisional application No. 60/609,304, filed on Sep. 13, 2004.
(60) Provisional application No. 60/715,464, filed on Sep. 9, 2005.

(51) Int. Cl. H03H 7/30

(52) U.S. Cl. 375/233

(57) ABSTRACT

The invention relates to techniques for pipelining parallel decision feedback decoders (PDFDs) for high speed communication systems, such as 10 Gigabit Ethernet over copper medium (10GBASE-T). In one aspect, the decoder applies look-ahead methods to two concurrent computation paths. In another aspect of the invention, retiming and reformulation techniques are applied to a parallel computation scheme of the decoder to remove all or a portion of a decision feedback unit (DFU) from a critical path of the computations of the pipelined decoder. In addition, the decoder may apply a pre-cancellation technique to a parallel computation scheme to remove the entire DFU from the critical path.

This application claims the benefit of U.S. Provisional Application No. 60/609,304, to Parhi et al., entitled “PIPELINED PARALLEL DECISION FEEDBACK DECODERS FOR HIGH-SPEED COMMUNICATION SYSTEMS,” filed Sep. 13, 2004, and U.S. Provisional Application No. ______, to Parhi et al., entitled “PIPELINED PARALLEL DECISION FEEDBACK DECODERS FOR HIGH-SPEED COMMUNICATION SYSTEMS,” having attorney docket no. 1008-030USP2, filed Sep. 9, 2005, the entire contents of each being incorporated herein by reference.

### STATEMENT REGARDING FEDERALLY SPONSORED RESEARCH FOR DEVELOPMENT

The invention was made with Government support from the National Science Foundation No. CCF-0429979. The Government may have certain rights in this invention.

### TECHNICAL FIELD

The invention relates to computer networks, more specifically to decoding data received from computer networks.

### BACKGROUND

Currently, local area networks (LANs) are utilizing Gigabit Ethernet over copper medium, a protocol commonly referred to as 1000BASE-T. The next generation high-speed Ethernet is 10 Gigabit Ethernet over copper medium, a protocol commonly referred to as 10GBASE-T. The Institute of Electrical and Electronic Engineers (IEEE) 802.3 10GBASE-T study group is investigating the feasibility of transmission of 10 Gigabits per second over 4 unshielded twisted pairs.

10GBASE-T will probably use a pulse amplitude modulation (PAM) scheme, such as PAM10 combined with a four dimensional trellis code as the basis for its transmission scheme. The symbol rate of this scheme is 833 M baud with each symbol representing 3 bits of information. One of the powerful yet simple algorithms to decode the code as well as to combat inter-symbol interference is the parallel decision-feedback decoding algorithm. However, the implementation and design of a parallel decision-feedback decoder (PDFD) which operates at 833 MHz is challenging due to the long critical path in the decoder structure.

Existing literature describes high-speed PDFD designs suitable for 1000BASE-T applications. However, most of the proposed techniques may not be suitable for 10GBASE-T. For example, the decision feedback pre-filtering technique only works for channels where the postcursor ISI's energy is concentrated on the first one or two taps. Otherwise, it may result in significant performance loss. Furthermore, the complexity is exponential with channel memory length, so it is only suitable for channels with short memory length while the channel memory length of 10GBASE-T is substantially longer than that of 1000BASE-T.

### SUMMARY

In general, the invention relates to techniques for pipelining parallel decision feedback decoders (PDFDs) for high speed communication systems, such as 10 Gigabit Ethernet over copper medium (10GBASE-T). In one aspect, the decoder applies look-ahead methods to two concurrent computation paths. In another aspect of the invention, retiming and reformulation techniques are applied to a parallel computation scheme of the decoder to remove all or a portion of a decision feedback unit (DFU) from a critical path of the computations of the pipelined decoder. In addition, the decoder may apply a pre-cancellation technique to a parallel computation scheme to remove the entire DFU from the critical path.

Utilization of pipelined PDFDs may enable network providers to operate 10 Gigabit Ethernet with copper cable rather than fiber optic cable. Thus, network providers may operate existing copper cable networks at higher speeds without having to incur the expense of converting copper cables to more expensive fiber optic cables. Furthermore, the pipelined PDFD techniques may reduce hardware overhead and complexity of the decoder.

In one embodiment, a parallel decision feedback decoder (PDFD) comprises a plurality of computational units, wherein the computational units are pipelined to produce a decoded symbol for each computational iteration.

In another embodiment, a method comprises receiving a signal from a network, and processing the signal with a parallel decision feedback decoder (PDFD) having a plurality of pipelined computational units to produce a decoded symbol for each computational iteration of the PDFD.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram illustrating an exemplary network communication system.

FIG. 2 is a block diagram illustrating an exemplary improved scheduling of computations in a PDFD algorithm.

FIG. 3 is a block diagram of a first exemplary high-speed PDFD architecture.

FIG. 4 is a block diagram illustrating an exemplary computation of look-ahead ID branch metrics.

FIG. 5 is a block diagram illustrating an exemplary 1D branch metric selection unit.

FIG. 6 is a block diagram illustrating an exemplary calculation of 4D branch metrics.

FIG. 7 is a block diagram illustrating an exemplary architecture of an ACSU for one code state.

FIG. 8 is a block diagram illustrating an exemplary architecture of a SMU.

FIGS. 9A-9E are block diagrams illustrating exemplary retiming and reformulation techniques for removing the LA DFU from the critical path.

FIG. 10 is a block diagram of a second exemplary high-speed PDFD architecture.

FIG. 11 is a block diagram illustrating an exemplary pre-cancellation technique and computation of LA 1D branch metrics.

FIG. 12 is a block diagram of a third exemplary high-speed PDFD architecture.

### DETAILED DESCRIPTION

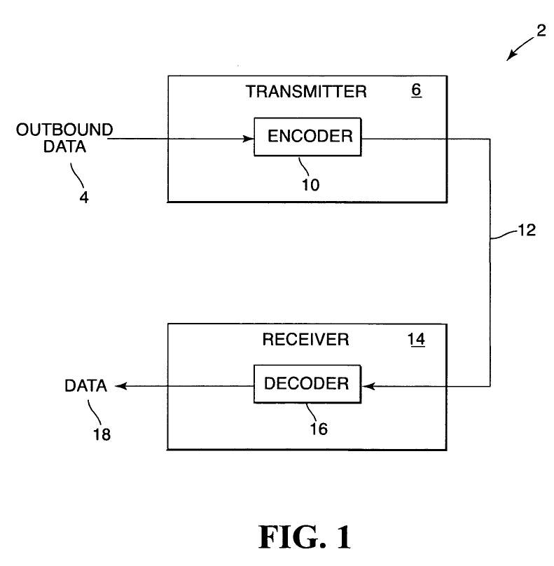

FIG. 1 is a block diagram of an exemplary network communication system 2. For purposes of the present description, communication system 2 will be assumed to be a 10 Gigabit Ethernet over copper network. Although the system will be described with respect to 10 Gigabit Ethernet over copper, it shall be understood that the present invention is not limited in this respect, and that the techniques described herein are not dependent upon the properties of the network. For example, communication system 2 could also be implemented within networks of various configurations utilizing one of many protocols without departing from the scope of the present invention.

In the example of FIG. 1, communication system 2 includes transmitter 6 and receiver 14. Transmitter 6 comprises encoder 10, which encodes outbound data 4 for transmission via network connection 12. Outbound data 4 may take the form of a stream of symbols for transmission to receiver 4. Once receiver 14 receives the encoded data, decoder 16 decodes the data resulting in decoded data 18, which may represent a stream of estimated symbols. In some cases decoded data 18 may then be utilized by applications within a network device that includes receiver 14.

In one embodiment, transmitter 6, located within a first network device (not shown), may transmit data to receiver 14, which may be located within a second network device (not shown). The first network device may also include a receiver substantially similar to receiver 14. The second network device may also include a transmitter substantially similar to transmitter 6. In this way, the first and second network devices may achieve two way communication with each other or other network devices. Examples of network devices that may incorporate transmitter 6 or receiver 14 include desktop computers, laptop computers, network enabled personal digital assistants (PDAs), digital televisions, or network appliances generally.

Decoder 16 may be a high-speed decoder such as a pipelined parallel decision feedback decoder (PDFD). Utilization of pipelined PDFDs may enable network providers to operate 10 Gigabit Ethernet with copper cable. For example, network providers may operate existing copper cable networks at higher speeds without having to incur the expense of converting copper cables to more expensive media, such as fiber optic cables. Furthermore, in certain embodiments of the invention, the pipelined PDFD design may reduce hardware overhead of the decoder. Although the invention will be described with respect to PDFD decoders, it shall be understood that the present invention is not limited in this respect, and that the techniques described herein may apply to other types of decoders.

Conventional PDFD algorithms perform computations in a serial manner. At time n, the conventional PDFD first computes inter-symbol interference (ISI) estimates. Next, these ISI estimates and the received samples are used to compute one dimensional (1D) branch metrics. Then the 1D branch metrics are added up to obtain four dimensional (4D) branch metrics. Lastly, the 4D branch metrics are used to update state metrics and survivor paths. This entire process is repeated at the next iteration. In this serial process, all of the computations are on the critical path.

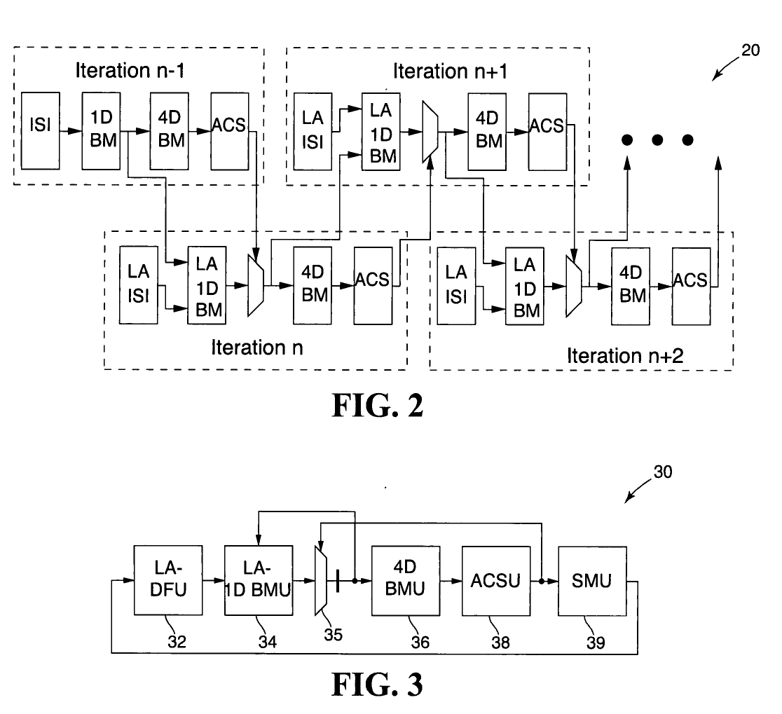

FIG. 2 is a block diagram illustrating an exemplary improved scheduling 20 of computations in a PDFD algorithm. Right after finishing the computation of 1D branch metrics (1D BM) for iteration n, the PDFD algorithm begins to pre-compute the branch metrics for the next iteration (n+1) since the two possible candidate 1D symbols for each wire are already known. The real 1D branch metrics are selected upon the completion of the add-compare-select (ACS) operation of iteration n. This process is repeated at the next time as illustrated in FIG. 2.

FIG. 3 is a block diagram of a first exemplary high-speed PDFD architecture 30, corresponding to the computation scheduling of FIG. 2. PDFD architecture 30 comprises two concurrent computation paths. Path one consists of look-ahead DFU (LA DFU) 32, look-ahead 1D branch metric unit (LA 1D BMU) 34, and 1D branch metric selection unit 35. The computation time of path one is 6 additions, one slicing operation, one random logic, and two multiplexing operations. The second path includes 4D BMU 36, add-compare-select unit (ACSU) 38, and survivor memory unit (SMU) 39. The computation time of the second path is 5 additions, one 4-to-1 multiplex operation, one 2-to-1 multiplex operation, and a random select logic. Thus, path one dominates the computation time and becomes the critical path in the proposed design. Compared with a straightforward implementation, it can achieve a speedup of around 1.5. The term “straightforward” refers to non-pipelined PDFDs and will be used throughout this detailed description.

At time n, look-ahead DFU 32 is used to compute partial ISI estimates for code state ρₙ₊₁ due to the channel coefficients {f_{2,j}, f_{3,j}, . . . , f_{N,j}} based on the already known survivor symbol sequence. Assuming there is a state transition between ρₙ and ρₙ₊₁, then the partial ISI estimate for ρₙ₊₁ corresponding to the transition can be calculated as:

$${\tilde{u}}_{n + 1 , j} ( {ρ}_{n} ) = - {\sum }_{i = 2}^{L} {f}_{i , j} {a}_{n - i + 1 , j} ( {ρ}_{n} ) . \qquad ( 1 )$$

Since there are 8 code states and 4 wires, altogether 32 look-ahead ISI estimates are needed to compute. The computation time of look-ahead DFU 32 is around 4 additions if we use carry-save adder structure.

The look-ahead 1D BMU 34 computes look-ahead 1D branch metrics for transitions departing from code states {ρₙ₊₁} Inputs to the look-ahead 1D BMU are partial ISI estimates {û_{n+1,j}(ρₙ)} due to {f_{2,j}, f_{3,j}, . . . , f_{N,j}} and the received sample z_{n+1,j}. In addition, look-ahead 1D BMU 34 needs to consider the ISI partial contribution due to the channel coefficient f_{1,j} and the 1D symbol decision a_{n,j}(ρₙ→ρₙ₊₁) associated with state transitions ρₙ→ρₙ₊₁. A speculative ISI estimate for the state transition ρₙ→ρₙ₊₁ can be calculated as

$${\hat{u}}_{n + 1 , j} ( {ρ}_{n} \to {ρ}_{n + 1} ) = {\hat{u}}_{n + 1 , j} ( {ρ}_{n} ) - {f}_{1 , j} {a}_{n , j} ( {ρ}_{n} \to {ρ}_{n + 1} ) = {\sum }_{i = 2}^{L} {f}_{i , j} {a}_{n - i + 1 , j} ( {ρ}_{n} ) - {f}_{1 , j} {a}_{n , j} ( {ρ}_{n} \to {ρ}_{n + 1} ) \qquad ( 2 )$$

Since pulse amplitude modulation ten (PAM10) is utilized, there are 10 possible choices for a_{n,j}(ρₙ→ρₙ₊₁) and in turn 10 possibilities for û_{n+1,j}(ρₙ→ρₙ₊₁). The high-speed PDFD architecture 30 (FIG. 3) enables a reduction in hardware overhead by feedbacking the previous 1D branch metric results (for transitions {ρₙ}→{ρₙ₊₁}) to the current calculation of the look-ahead 1D branch metrics. After the completion of 1D branch metrics for transitions departing from a state ρₙ, there are only two possible choices for a_{n,j} associated with the state transition ρₙ→ρₙ₊₁, one a_{n,j}(ρₙ, A)) from subset A and the other a_{n,j}(ρₙ, B)) from subset B. In addition, as is evident from equation:
λₙ(r_{n,j},a_{n,j},ρₙ)=(r_{n,j}−a_{n,j}+u_{n,j}(ρₙ))² (3)
the two possibilities for a_{n,j} are only dependent on ρₙ. Thus, there are only two possibilities for û_{n+1,j}(ρₙ→ρₙ₊₁). Therefore, the only pre-computations needed are look-ahead 1D branch metrics for the 2 possibilities, resulting in a high hardware reduction.

As the two possible choices for a_{n,j}(ρₙ→ρₙ₊₁) are only dependent on the initial state ρₙ, the possible ISI estimates for state ρₙ₊₁ are only dependent on ρₙ too. For code states {ρₙ₊₁=0,1,2,3}, as they have the same predecessor states {ρₙ=0,2,4,6}, their LA 1D branch metrics are the same. Therefore, LA 1D branch metrics for only one of them needs to be computed. This is also true for code states {ρₙ₊₁=4,5,6,7}. For wire j and initial code state ρₙ four look-ahead 1D branch metrics are needed to be calculated according to:
\hat{λ}_{n+1,j}(r_{n+1,j},a_{n+1,j},ρₙna_{n,j})=(r_{n+1,j}−aₙ₊₁+u_{n+1,j}(ρₙ)−f_{1,j}a_{n.,j})² (4)
with two (one per 1D subset for a_{n+1,j}) for a_{n,j}=a_{n,j}(ρₙ, A) and two for a_{n,j}=a_{n,j}(ρₙ, B). As there are eight code states and four wires, altogether 8×4×4=128 1D look-ahead branch metrics are needed to compute. This is a reduction to the 640 look-ahead branch metrics which are needed to compute in straightforward implementations.

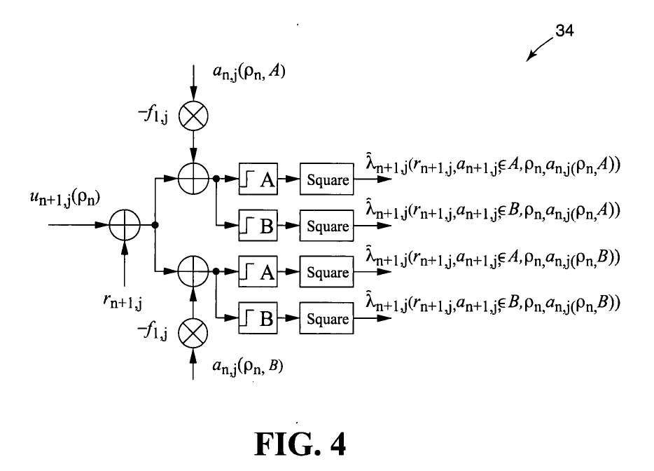

FIG. 4 is a block diagram illustrating an exemplary computation of look-ahead 1D branch metrics 34, corresponding to LA 1D BMU within high-speed PDFD architecture 30 (FIG. 3). The inputs are the received sample r_{n+1,j} the look-ahead ISI estimate u_{n+1,j}(ρₙ), and the two possible candidates for the transmittal symbol a_{n,i} associated with the state ρₙ, obtained from the last iteration. As illustrated in FIG. 4, the computation time of look-ahead 1D BMU 34 consist of two additions, one slicing operation, and one squaring function.

For code state ρₙ₊₁ and wire j, two real 1D metrics (one for a_{n,j}εA and one for B) need to be selected among 16 precomputed branch metrics (four from each of 4 predecessor states of ρₙ₊₁).

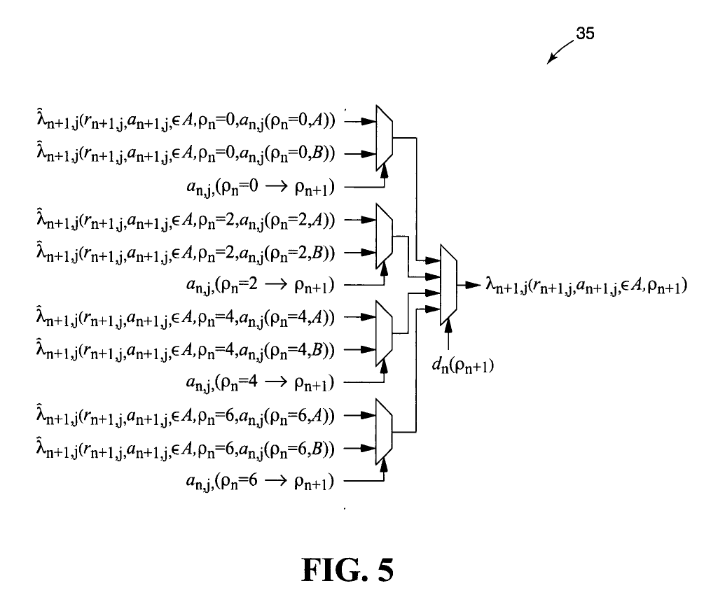

FIG. 5 is a block diagram illustrating an exemplary 1D branch metric selection unit 35, corresponding to 1D branch metric selection unit within high-speed PDFD architecture 30 (FIG. 3). FIG. 5 shows the selection for the A-type branch metric λ_{n+1,j}(rₙ₊₁, a_{n+1,j}(ρₙ₊₁=0, A), ρ₊₁=0). The inputs are 8 eight precomputed branch metrics with two from each of 4 predecessor states, the 1D symbol decision associated with state transition ρₙ→ρₙ₊₁ from the 4D BMU, and the ACSU decision dₙ(ρₙ₊₁). The computation time of the selection operation is two multiplexing operations.

4D branch metrics 36 (FIG. 3) are obtained by just adding up the 1D branch metrics from the 1D BMU according to:

$${λ}_{n} ( {r}_{n} , {a}_{n} , {ρ}_{n} ) = {\sum }_{j = 1}^{4} {λ}_{n , j} ( {r}_{n , j} , {a}_{n , j} , {ρ}_{n} ) \qquad ( 5 )$$

For each state transition ρₙ→ρₙ₊₁ two 4D branch metrics (one is associated with an A-type 4D symbol and the other B-type) are needed to be computed. The smaller metric (referred to as λₙ(rₙ, aₙ, ρₙ→ρₙ₊₁) and its associated 4D symbol aₙ(ρₙ→ρₙ₊₁) are selected to be used in ACSU 38.

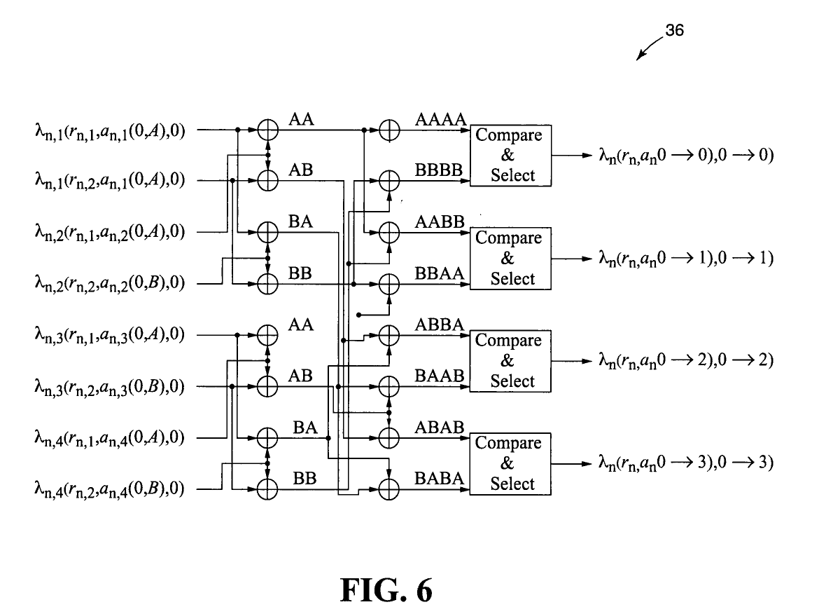

FIG. 6 is a block diagram illustrating an exemplary calculation of 4D branch metrics 36 of branches departing from state 0, corresponding with 4D branch metrics within high-speed PDFD architecture 30 (FIG. 3). The computation time of the 4D BMU is 3 additions and one 2-to-1 multiplexing operation.

ACSU 38 (FIG. 3) is used to determine the best survivor path into code state ρₙ₊₁ from its four predecessor states by performing the four-way add-compare-select (ACS) operation:

$${Γ}_{n + 1} ( {ρ}_{n + 1} ) {=}_{{ρ}_{n} \to {ρ}_{n + 1}}^{min} \{ {Γ}_{n} ( {ρ}_{n} ) + {λ}_{n} ( {r}_{n} , {a}_{n} ( {ρ}_{n} \to {ρ}_{n + 1} ) , {ρ}_{n} \to {ρ}_{n +} ) \} \qquad ( 6 )$$

The outputs of ACSU 38 are the newly decoded 4D survivor symbol aₙ(ρₙ₊₁) and path selection decision dₙ(ρₙ₊₁). The outputs are used to update the survivor sequence. The new sequence will be used to compute ISI estimates in the next iteration.

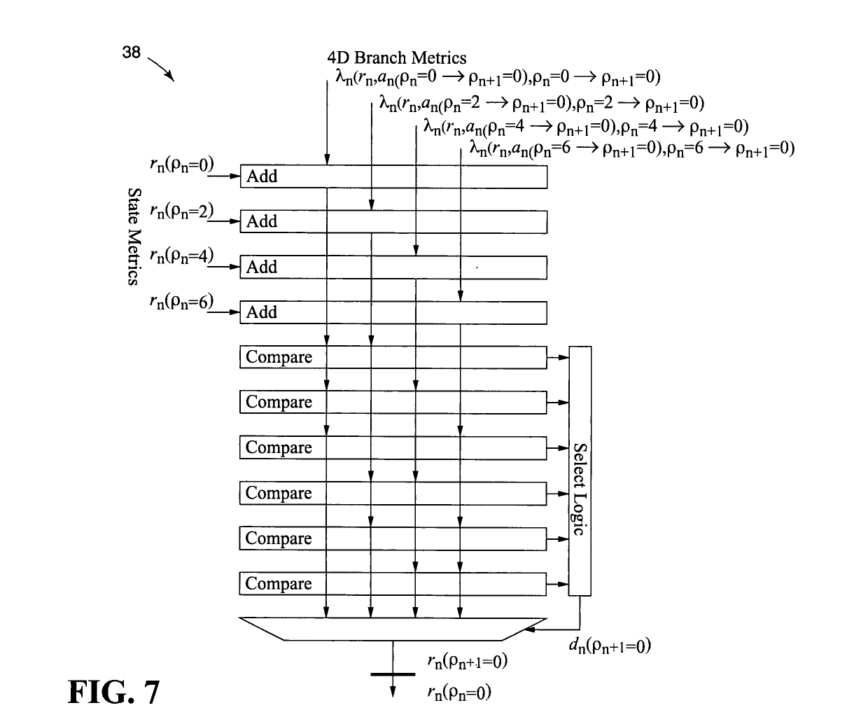

FIG. 7 is a block diagram illustrating an exemplary architecture of ACSU 38 for one code state, corresponding with 4D branch metrics within high-speed PDFD architecture 30 (FIG. 3). The computation time of ACSU 38 consists of two additions, one random select operation and one 4-to-1 multiplexing operation.

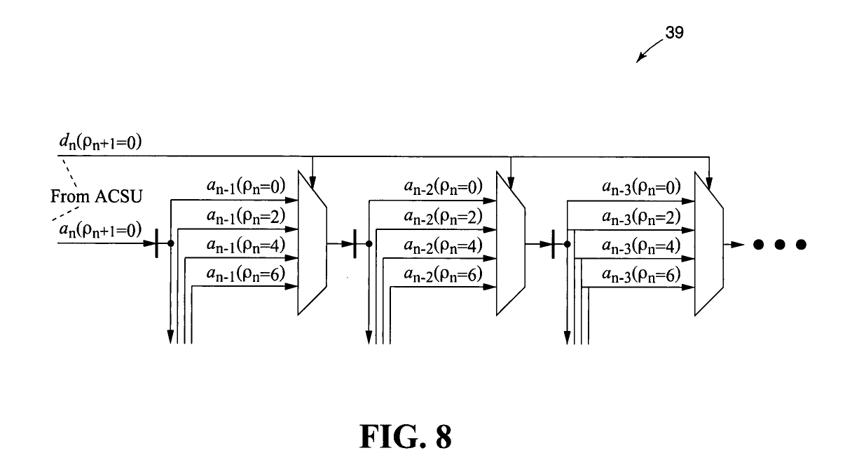

FIG. 8 is a block diagram illustrating an exemplary architecture of SMU 39, corresponding with SMU within high-speed PDFD architecture 30 (FIG. 3). SMU 39 is register exchange architecture, which is applicable to high-speed applications. Optionally, SMU 39 may utilize a trace-back architecture. The survivor sequences merge after 5 to 6 times code memory length. Thus, the decoding depth is assumed to be 18. The computation time of SMU 39 is one 4-to-1 multiplexing operation.

As illustrated in FIG. 3, path one of high-speed PDFD architecture 30, consisting of LA DFU, LA 1D BMU, and 1D branch metric selection unit, dominates the computation time and becomes the critical path in high-speed PDFD architecture 30. As will be described below, removing all or a portion of the LA DFU from the critical path results in additional high-speed PDFD architectures.

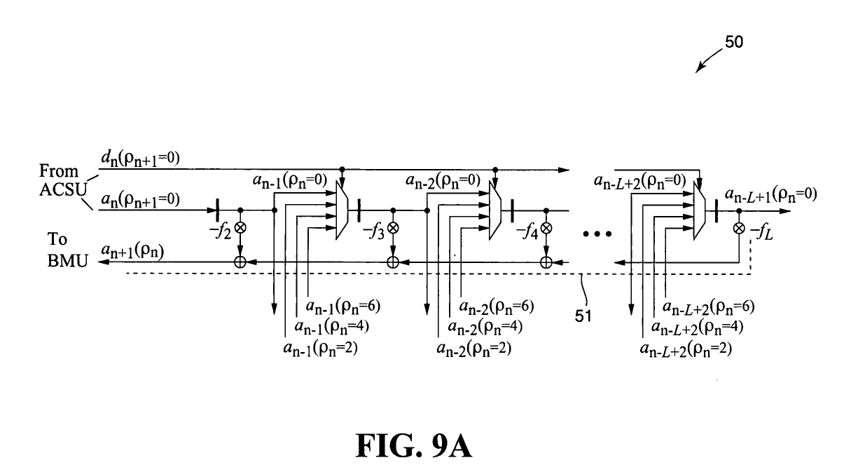

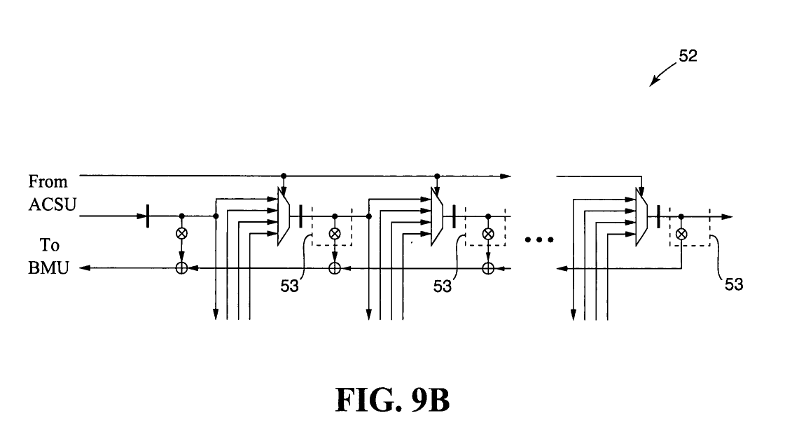

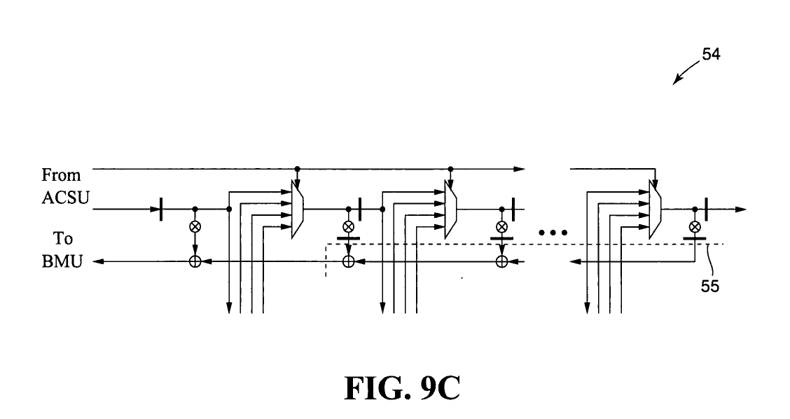

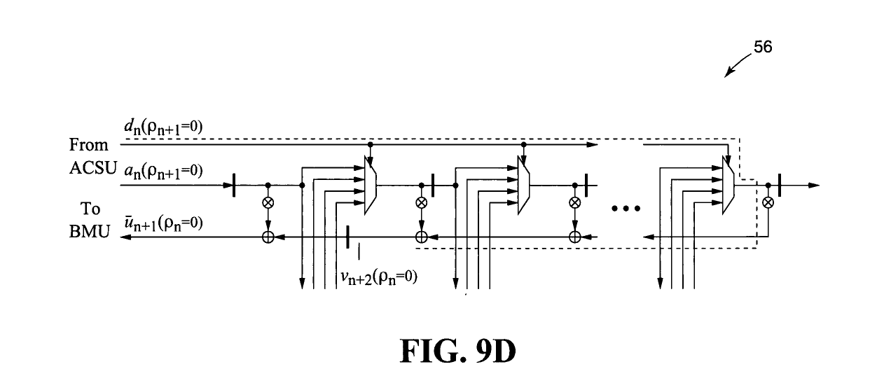

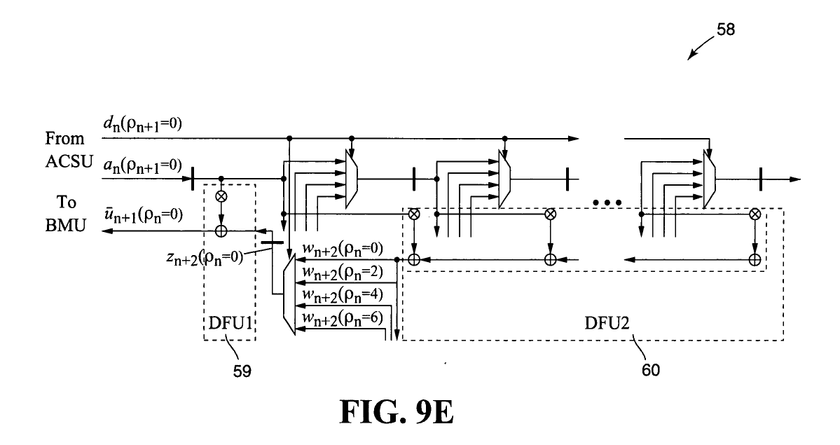

FIGS. 9A-9E are block diagrams illustrating exemplary retiming and reformulation techniques for removing the LA DFU from the critical path. FIG. 9A is a block diagram of an exemplary composite architecture 50 for LA DFU 34 and SMU 39 within high-speed PDFD architecture 30 (FIG. 3). FIG. 9A illustrates a long-chain of adders, as shown by dashed line 51, which are directly connected to the 1D BMU, resulting in a long critical path.

FIG. 9B is a block diagram illustrating an exemplary first retiming cutset 52. The long chain of adders from the BMU are isolated by using the retime cutsets shown by dotted lines 53 in FIG. 9B. The resulting circuit 54 is illustrated in FIG. 9C. Applying retiming again using cutest 55 illustrated in FIG. 9C, the retimed DFU 56 of FIG. 9D is obtained. However, in FIG. 9D the long chain of adders is now connected to the ACSU through a multiplexer, and the DFU is still on the critical path. Moving the multipliers before the corresponding multiplexers results in delays between the long chain of adders and the ACSU. This is done by performing the following reformulation:

$$\begin{matrix}{\sum }_{i = 3}^{L} Sel ( {d}_{n} ( {ρ}_{n + 1} = 0 ) , {a}_{n - i + 2} ( {ρ}_{n} = 0 ) , \\ {a}_{n - i + 2} ( {ρ}_{n} = 2 ) , {a}_{n - i + 2} ( {p}_{n} = 4 ) , \\ {a}_{n - i + 2} ( {ρ}_{n} = 6 ) ) ⋆ {f}_{i} \\ = Sel ( {d}_{n} ( {ρ}_{n + 1} = 0 ) , {\sum }_{i = 3}^{L} {a}_{n - 1 + 2} ( {ρ}_{n} = 0 ) {f}_{i} , \\ {\sum }_{i = 3}^{L} {a}_{n - i + 2} ( {ρ}_{n} = 2 ) {f}_{i} , {\sum }_{i = {3}_{}}^{L} {a}_{n - 1 + 2} ( {ρ}_{n} = 4 ) {f}_{i} {,}_{} \\ {\sum }_{i = 3}^{L} {a}_{n - 1 + 2} ( {ρ}_{n} = 6 ) {f}_{i} ) ,\end{matrix} \qquad ( 7 )$$

where Sel(d, x₀,x₁,x₂,x₃) is a 4-to-1 multiplexing function and depending on d, Sel(d, x₀,x₁,x₂ ,x₃) selects one of xᵢ, i=0,1,2,3 as its output.

FIG. 9E illustrates reformulated DFU 58. DFU 58 is divided into two parts, DFU 1 (59) and DFU 2 (60). The major part, DFU 2 (60), which has a long chain of adders, is now isolated from both of the BMU and ACSU and is no longer on the critical path. Part of the DFU, DFU 1 (59) is still directly connected to the BMU, which may contribute to the critical path of the design in FIG. 3. The DFU may be completely removed from the critical path by using pre-computation to DFU 1 (59).

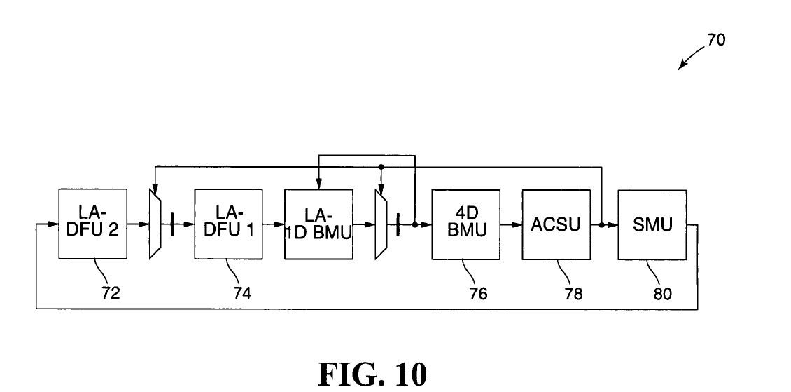

FIG. 10 is a block diagram of a second exemplary high-speed PDFD architecture 70. By utilizing the retiming and reformulating techniques illustrated in FIG. 9E, LA DFU 1 (74) and LA DFU 2 (72) are included in high-speed PDFD architecture 70. The computation path is pipelined into three stages. The critical path only includes 4-D BMU 76, ACSU 78, and SMU 80. LA DFU 1 (74) is moved to the LA 1D BMU path. As illustrated in FIG. 9E, the computation time of the LA DFU 1 (74) is only one addition. Depending on the detailed design, the critical path may be the one which includes 4D BMU, ACSU and SMU or the one with LA DFU 1 and LA 1D BMU. Compared with the straightforward design, high-speed PDFD architecture 70 achieves a speedup of around 2.

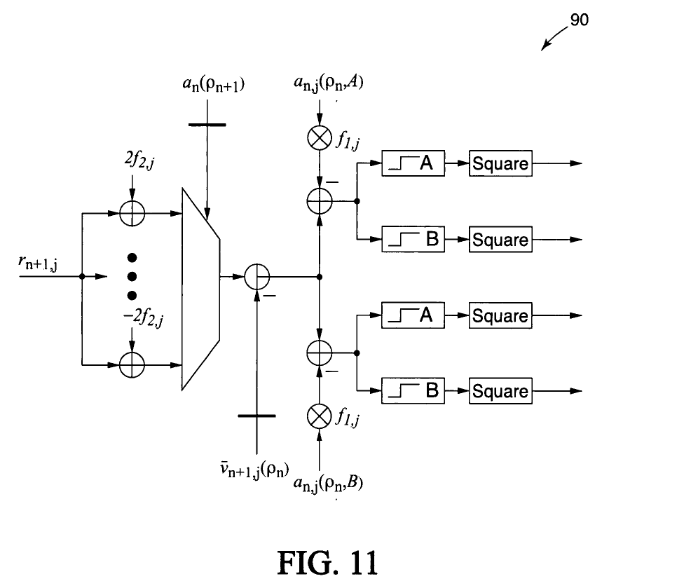

FIG. 11 is a block diagram illustrating an exemplary pre-cancellation technique and computation of LA 1D branch metrics (90), which may further reduce hardware overhead. The ISI contribution from the postcursor coefficient f_{2,j} for the received sample r_{n+1,j} is pre-cancelled, and the DFU 1 is removed. Since there are five possibilities for each transmitted symbol a_{n-1,j}, pre-computation technique is used to compute r_{n+1,j}−f_{2,j}a_{n-1,j}. The real transmitted symbol is chosen by using a multiplexer, and then the transmitted symbol is sent to the BMU. The precomputation of r_{n+1,j}−f_{2,j}a_{n-1,j} is easily isolated from the critical path by cutset pipelining. The hardware overhead is reduced to 4*5=20 adders and a multiplexer array.

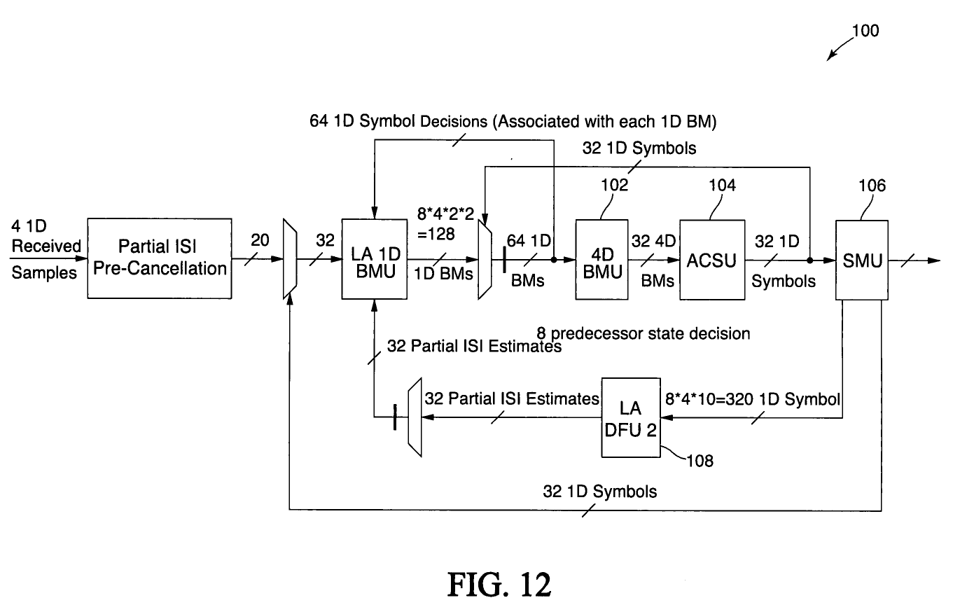

FIG. 12 is a block diagram of a third exemplary high-speed PDFD architecture 100, which utilizes the pre-cancellation technique 90 (FIG. 11). The computation path in high-speed PDFD architecture 100 is also pipelined into three stages. The critical path is the path which includes 4D-BMU 102, ACSU 104 and SMU 106. The LA DFU 2 (108) is removed from the critical path. Compared with the straight-forward implementation, high-speed PDFD architecture 100 achieves a speedup of around 2.

The proposed techniques in the previous sections are also applicable to other applications and trellis coded modulation schemes other than the one described in this paper. The proposed techniques may be used for any applications where it is necessary to decode trellis encoded signals in the presence of inter-symbol interference and noise. For example, the proposed techniques may be used for 1000BASE-T which uses a 5-level PAM modulation combined with a 4D 8-state trellis code.

Various embodiments of the invention have been described. These and other embodiments are within the scope of the following claims.

1. A parallel decision feedback decoder (PDFD) comprising a plurality of computational units, wherein the computational units are pipelined to produce a decoded symbol for each computational iteration.

2. The PDFD of claim 1, wherein the plurality of computational units includes a branch metric unit that pre-computes branch metrics for use in selecting the decoded symbol.

3. The PDFD of claim 2, wherein an output from the branch metric unit for a current symbol is provided as feedback to the branch metric unit for pre-computing branch metrics for a subsequent decoded symbol.

4. The PDFD of claim 2, wherein one of the computational units comprises a selection unit that selects the decoded symbols based on the pre-computed branch metrics.

5. The PDFD of claim 4, wherein the selection unit selects the decoded symbol by determining a set of real branch metrics from the pre-computed branch metrics.

6. The PDFD of claim 5, wherein the selection unit computes a plurality of path selection decisions in parallel and selects one of the paths as a function of the pre-computed branch metrics to select the decoded symbol.

7. The PDFD of claim 1, wherein the computational units comprise a decision feedback unit (DFU) that computes inter-symbol interference estimates, wherein the DFU comprises a first portion that computes inter-symbol interference estimates for a plurality of symbols, and a second portion that outputs the inter-symbol interference estimates for a current symbol.

8. The PDFD of claim 7, wherein only the second portion of the DFU resides on a critical path of the pipelined computational units.

9. The PDFD of claim 7, wherein the first portion and the second portion of the DFU reside on a path other than a critical path of the pipelined computation units.

10. The PDFD of claim 1, wherein one of the computational units computes partial inter-symbol interference estimates to pre-cancel inter-symbol interference contributions from a symbol other than the current symbol.

11. A method comprising:
receiving a signal from a network; and
processing the signal with a parallel decision feedback decoder (PDFD) having a plurality of pipelined computational units to produce a decoded symbol for each computational iteration of the PDFD.

12. The method of claim 11, wherein processing comprises pre-computing branch metrics for use in selecting the decoded symbol.

13. The method of claim 12, wherein processing comprises:
feeding back an output from a branch metric unit of the PDFD for a current symbol to the branch metric unit; and
pre-computing branch metrics for a subsequent decoded symbol based on the fed back output.

14. The method of claim 12, wherein processing comprises selecting the decoded symbols based on the pre-computed branch metrics.

15. The method of claim 14, wherein selecting comprises determining a set of real branch metrics from the pre-computed branch metrics.

16. The method of claim 15, wherein determining a set of real branch metrics comprises:
computing a plurality of path selection decisions in parallel; and
selecting one of the paths as a function of the pre-computed branch metrics.

17. The method of claim 11, wherein processing comprises computing inter-symbol interference (ISI) estimates with a decision feedback unit (DFU) of the PDFD.

18. The method of claim 17, wherein computing ISI estimates comprises performing one or more computations for the ISI estimates within a portion of the DFU removed from a critical path of the PDFD.

19. The method of claim 18, wherein computing ISI estimates comprises computing all of the computations within the portion of the DFU removed from the critical path of the PDFD.

20. The method of claim 17, wherein computing ISI estimates comprise:
computing inter-symbol interference estimates for a plurality of symbols with a first portion of the DFU; and
outputting the inter-symbol interference estimates for a current symbol with a second portion of the DFU.

21. The method of claim 11, wherein processing comprises computing partial ISI estimates to pre-cancel ISI contributions from a symbol other that the current symbol.
